(19) United States
(12) Patent Application Publication
(10) Pub. No.: US 2025/0239554 A1
(43) Pub. Date: Jul. 24, 2025

(54) SEMICONDUCTOR PACKAGE

(71) Applicant: Samsung Electronics Co., Ltd., Suwon-si (KR)

(72) Inventors: Wonil Seo, Suwon-si (KR); Kundae Yeom, Suwon-si (KR); Jiwon Shin, Suwon-si (KR)

(21) Appl. No.: 18/920,395

(22) Filed: Oct. 18, 2024

(30) Foreign Application Priority Data
Jan. 22, 2024 (KR) 10-2024-0009343

(51) Int. Cl. H01L 23/00; H01L 23/31; H01L 23/538; H01L 25/065

(52) U.S. Cl. CPC H01L 24/16; H01L 23/3128; H01L 23/5386; H01L 24/05; H01L 24/13; H01L 24/17; H01L 24/32; H01L 25/0657; H01L 2224/05124; H01L 2224/05554; H01L 2224/05573; H01L 2224/05687; H01L 2224/13018; H01L 2224/13022; H01L 2224/16245; H01L 2224/1713; H01L 2224/32145; H01L 2224/32225; H01L 2225/06513; H01L 2225/06517; H01L 2225/06524; H01L 2225/06562; H01L 2924/384

(57) ABSTRACT

A semiconductor package includes a package substrate including upper pads, semiconductor chips stacked in a first direction and each semiconductor chip including bonding pad structures respectively disposed at one side of an upper surface thereof and spaced apart from each other in a second direction, first connection bumps on the bonding pad structures, each first connection bump electrically connected to a respective bonding pad structure, second connection bumps on the upper pads, each second connection bump electrically connected to a corresponding bonding pad structure and a corresponding upper pad, an interconnection pattern extending in a third direction on the package substrate and the semiconductor chips and electrically connecting each of the first connection bumps at each level to a corresponding first connection bump located at a different level.

### CROSS-REFERENCE TO RELATED APPLICATION(S)

This application claims benefit of priority to Korean Patent Application No. 10-2024-0009343 filed on Jan. 22, 2024, in the Korean Intellectual Property Office, the disclosure of which is incorporated herein by reference in its entirety.

### BACKGROUND

The present inventive concept relates to a semiconductor package.

Recently, there has been demand for increased performance and high capacity of semiconductor packages installed in electronic devices. Accordingly, semiconductor packages including a plurality of semiconductor chips and control chips controlling operations of semiconductor chips have been developed.

### SUMMARY

An aspect of the present inventive concept is to provide a semiconductor package with improved performance and reliability.

According to an aspect of the present inventive concept, a semiconductor package includes a package substrate including an insulating layer, a wiring circuit in the insulating layer, upper pads electrically connected to the wiring circuit, and lower pads electrically connected to the wiring circuit, a plurality of semiconductor chips stacked in a first direction, perpendicular to an upper surface of the package substrate, and each semiconductor chip of the plurality of semiconductor chips including bonding pad structures respectively disposed at one side of an upper surface thereof and spaced apart from each other in a second direction intersecting the first direction, first connection bumps on the bonding pad structures, each first connection bump electrically connected to a respective bonding pad structure, second connection bumps on the upper pads, each second connection bump electrically connected to a corresponding bonding pad structure and a corresponding upper pad, an interconnection pattern extending in a third direction intersecting the first direction and the second direction on the package substrate and the plurality of semiconductor chips and electrically connecting each of the first connection bumps at each level to a corresponding first connection bump of the first connection bumps located at a different level, and external connection conductors on a lower surface of the package substrate and each of the external connection conductors electrically connected to a respective lower pad.

According to an aspect of the present inventive concept, a semiconductor package includes a package substrate including a wiring circuit, with an upper pad and a lower pad each electrically connected to the wiring circuit, a plurality of semiconductor chips stacked in a first direction, perpendicular to an upper surface of the package substrate, and including bonding pad structures respectively disposed at one side of an upper surface thereof and spaced apart from each other in a second direction, connection bumps disposed on the bonding pad structures and electrically connected to respective semiconductor chips through the bonding pad structures, interconnection patterns disposed on the package substrate and the plurality of semiconductor chips and each of the interconnection patterns electrically connecting corresponding connection bumps located at different levels, and a bonding wire electrically connecting the upper pad to at least one of the connection bumps. Each of the interconnection patterns are arranged at different levels, and a top of the bonding wire is located at a level lower than a top of at least one of the interconnection patterns.

According to an aspect of the present inventive concept, a semiconductor package includes a package substrate including a wiring circuit, at least one semiconductor chip disposed on an upper surface of the package substrate and including bonding pad structures disposed on one side of an upper surface thereof and spaced apart from each other in a first direction, connection bumps respectively disposed on the bonding pad structures and having a protruding portion in a first direction perpendicular to the upper surface of the package substrate, and an interconnection pattern extending in a second direction intersecting the first direction on the package substrate and the at least one semiconductor chip and electrically connecting corresponding connection bumps located on different levels. The interconnection pattern covers at least a portion of a side surface of the corresponding connection bumps.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a top view schematically illustrating a semiconductor package according to an embodiment of the present inventive concept;

FIG. 2A is a cross-sectional view illustrating a semiconductor package according to an embodiment of the present inventive concept, and FIG. 2B is a partially enlarged view illustrating region ‘A’ of FIG. 2A;

FIG. 3 is a top view schematically illustrating a semiconductor package according to an embodiment of the present inventive concept;

FIG. 4 is a cross-sectional view illustrating a semiconductor package according to an embodiment of the present inventive concept;

FIG. 5 is a top view schematically illustrating a semiconductor package according to an embodiment of the present inventive concept;

FIG. 6 is a cross-sectional view illustrating a semiconductor package according to an embodiment of the present inventive concept; and

FIGS. 7A, 7B, 8A, 8B, 9A, 9B, and 10 are cross-sectional views and partially enlarged views schematically illustrating a manufacturing process of a semiconductor package according to an embodiment of the present inventive concept.

### DETAILED DESCRIPTION

Hereinafter, embodiments of the present inventive concept are described with reference to the accompanying drawings. The inventive concept may, however, be embodied in many different forms and should not be construed as limited to the example embodiments set forth herein. It should also be emphasized that the disclosure provides details of alternative examples, but such listing of alternatives is not exhaustive. Furthermore, any consistency of detail between various examples should not be interpreted as requiring such detail. The language of the claims should be referenced in determining the requirements of the invention.

Unless otherwise specified, in this specification, terms such as ‘upper portion,’ ‘upper surface,’ ‘lower portion,’ ‘lower surface,’ ‘side surface,’ etc. are based on orientation shown in the drawings, and may differ in the directions when components are arranged in other orientations. Items described in the singular herein may be provided in plural, as can be seen, for example, in the drawings. Thus, the description of a single item that is provided in plural should be understood to be applicable to the remaining plurality of items unless context indicates otherwise.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

As used herein, components described as being “electrically connected” are configured such that an electrical signal can be transferred from one component to the other (although such electrical signal may be attenuated in strength as it is transferred and may be selectively transferred). Moreover, components that are “directly electrically connected” share a common electrical node through electrical connections by one or more conductors, such as, for example, wires, pads, internal electrical lines, through vias, etc. As such, directly electrically connected components do not include components electrically connected through active elements, such as transistors or diodes.

Throughout the specification, when a component is described as “including” a particular element or group of elements, it is to be understood that the component is formed of only the element or the group of elements, or the element or group of elements may be combined with additional elements to form the component, unless the context clearly and/or explicitly describes the contrary. The term “consisting of,” on the other hand, indicates that a component is formed only of the element(s) listed.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

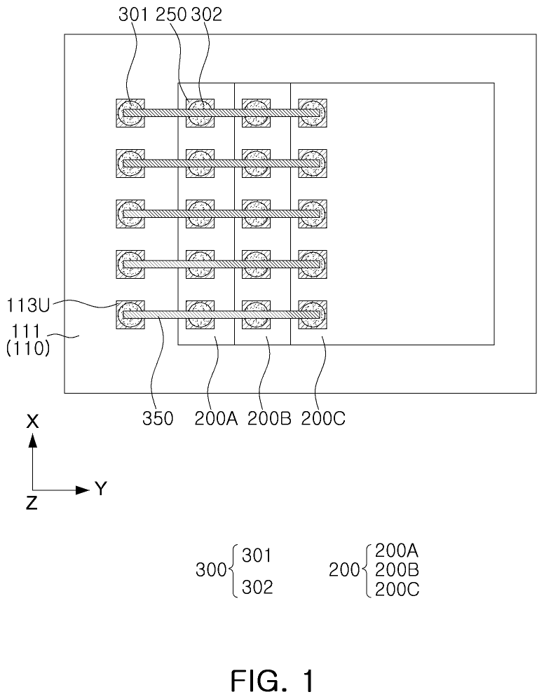

FIG. 1 is a top view schematically illustrating a semiconductor package according to an embodiment of the present inventive concept.

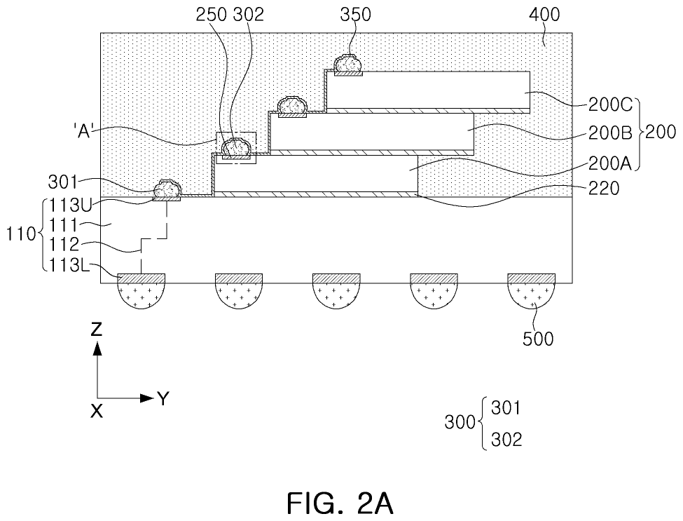

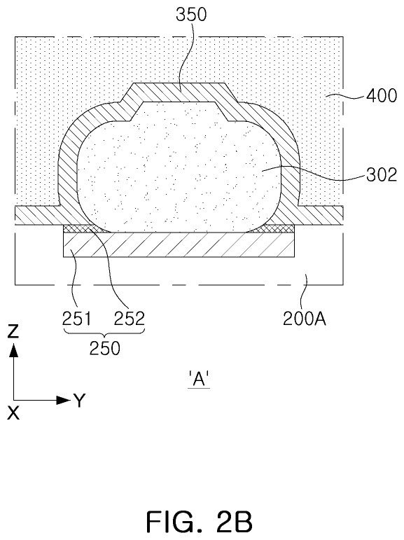

FIG. 2A is a cross-sectional view illustrating a semiconductor package according to an embodiment of the present inventive concept, and FIG. 2B is a partially enlarged view illustrating region ‘A’ of FIG. 2A.

Referring to FIGS. 1, 2A, and 2B, a semiconductor package 100A of an embodiment may include a package substrate 110, a plurality of semiconductor chips 200, connection bumps 300, and interconnection patterns 350. Referring to FIGS. 1, 2A, and 2B, the semiconductor package 100A of an embodiment may further include an encapsulant 400 and external connection conductors 500.

The package substrate 110 may include an insulating layer 111 and at least one wiring circuit 112. The at least one wiring circuit 112 may include a plurality of wiring circuits 112 and each wiring circuit 112 may be disposed at a different level. The plurality of wiring circuits may collectively be referred to as a wiring circuit 112. The package substrate 110 may further include a via structure that electrically connects the wiring circuits 112 located at different levels. The package substrate 110 may be a semiconductor package substrate including a printed circuit board (PCB), a ceramic substrate, a glass substrate, or a tape wiring board.

The insulating layer 111 may include an insulating resin. The insulating resin may include a thermosetting resin, such as an epoxy resin, a thermoplastic resin, such as polyimide, or a resin obtained by impregnating these resins with an inorganic filler and/or a glass fiber (or a glass cloth or a glass fabric), e.g., a prepreg, an Ajinomoto build-up film (ABF), FR-4, or bismaleimide triazine (BT). The insulating resin may include a photosensitive resin, such as photoimageable dielectric (PID) resin. For example, when the package substrate 110 is a PCB, the insulating layer 111 may be a core insulating layer (e.g., prepreg) of a copper clad laminate. The insulating layer 111 may have a form in which a large number of insulating layers are stacked in a vertical direction (e.g., a Z-axis direction), and depending on the process, the boundaries between the first insulating layers on different levels may be inapparent.

The wiring circuit 112 may be disposed within the insulating layer 111 and may form electrical paths within the package substrate 110. The wiring circuit 112 may include at least one of copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), and carbon (C), or alloys of two or more metals thereof.

Upper pads 113U may be disposed at an upper surface of the insulating layer 111 and lower pads 113L may be disposed at a lower surface of the insulating layer 111. The upper pads 113U and lower pads 113L may be electrically connected through the wiring circuit 112. The upper pads 113U may be electrically connected to the plurality of semiconductor chips 200 on the insulating layer 111 through the interconnection pattern 350, and the lower pads 113L may be electrically connected to the plurality of external connection conductors 500 below the insulating layer 111.

The upper pads 113U and lower pads 113L may include the same material as that of the wiring circuit, but are not limited thereto. In an embodiment, the upper pads 113U may include at least one metal selected from copper (Cu), nickel (Ni), and gold (Au), or alloys of two or more metals thereof, but are not limited thereto.

The plurality of semiconductor chips 200 may include, but is not limited to, semiconductor chips 200A, 200B, and 200C stacked in a direction perpendicular to an upper surface of the package substrate 110 (e.g., a vertical direction), but without being limited thereto, a larger number of semiconductor chips may also be provided. Stacked semiconductor chips indicates that the semiconductor chips are disposed with a lowermost semiconductor chip 200A at a lower end of the stack and an uppermost semiconductor chip at an upper end of the stack with intermediate semiconductor chips positioned therebetween in the vertical direction. The plurality of semiconductor chips 200 may overlap each other in the vertical direction (e.g., the Z-axis direction), perpendicular to the upper surface of the package substrate 110. The plurality of semiconductor chips 200 may be stacked to be offset in a first direction (e.g., an X-axis direction, which may be a horizontal direction) such that a portion of an upper surface of each semiconductor chip is exposed and not covered by a semiconductor chip immediately above. The exposed upper surface may be adjacent to one side of the semiconductor chip immediately above the upper surface, but the present inventive concept is not limited thereto. The plurality of semiconductor chips 200 may be arranged in a staircase shape with a portion of each upper surface thereof exposed from the other semiconductor chips. In an embodiment, the plurality of semiconductor chips 200 may be aligned in a configuration other than offset in the same direction, and may be arranged, for example, in a zigzag shape with some semiconductor chips 200 being offset in the first direction and other semiconductor chips 200 being offset opposite the first direction.

Among the plurality of semiconductor chips, the lowermost semiconductor chip 200A may be a bare integrated circuit (IC) without separate bumps or wiring layers, but is not limited thereto and may be a packaged type of integrated circuit. The integrated circuit may be a processor chip, such as a central processing unit (CPU), graphics processing unit (GPU), field programmable gate array (FPGA), application processor (AP), digital signal processor, cryptographic processor, microprocessor, or microcontroller, but, without being limited thereto, the integrated circuit may include logic chips, such as an analog-to-digital converter (ADC) or application-specific IC (ASIC), or memory chips including volatile memories, such as dynamic RAM (DRAM) and static RAM (SRAM), and nonvolatile memories, such as phase change RAM (PRAM), MAGNETIC ram (MRAM), resistive RAM (RRAM), and flash memory. The semiconductor chips 200B and 200C, which may be an intermediate semiconductor chip 200B and an uppermost semiconductor chip 200C, stacked on the lowermost semiconductor chip 200A may have characteristics the same as or similar to the lowermost semiconductor chip 200A.

The plurality of semiconductor chips 200 may include bonding pad structures 250 disposed to be adjacent to one side on upper surfaces thereof and spaced apart from each other in the first direction (e.g., the X-axis direction). The bonding pad structures 250 may include a conductive pad 251 and an oxide film 252 disposed on the conductive pad 251. The conductive pad 251 may include a conductive material. In an embodiment, the conductive pad 251 may include aluminum (Al) but is not limited thereto. The conductive pad 251 may be electrically connected to an internal circuit of the semiconductor chip 200 and may transmit an electrical signal from the internal circuit. The oxide film 252 may include an insulating material and may include an oxide. On a plane, the oxide film 252 may have a square shape with a central portion thereof removed (e.g., a square ring). An upper surface of the oxide film 252 may be located at the same level as an upper surface of the corresponding semiconductor chip.

The plurality of semiconductor chips 200 may be attached to each other by an adhesive film 220 (e.g., DAF), and the lowermost semiconductor chip 200A may be attached to the upper surface of the package substrate 110 by the adhesive film 220.

The connection bumps 300 may include first connection bumps 301 disposed on the upper pads 113U and second connection bumps 302 disposed on the bonding pad structures 250. The connection bumps 300 may each include a metal material, for example, tin (Sn) or an alloy containing tin (Sn) (e.g., Sn—Ag—Cu). The connection bumps 300 may each have a ball shape or a ball shape with an upper end protruding relative to the ball shape. On a plane, the connection bumps 300 may each have a circular shape. Each of the connection bumps 300 may be electrically connected to a corresponding upper pad 113U and at least one corresponding bonding pad structure 250. Specifically, each connection bump 300 may be in contact with an upper surface of a corresponding conductive pad 251 and may be electrically connected to the respective conductive pad 251. Each connection bump 300 may be in contact with an inner surface of the oxide film 252 having a square ring shape on a plane of the corresponding conductive pad 251. At least a portion of the connection bump 300 may be surrounded by the oxide film 252. By including a structure in which, on a plane, the oxide film 252 is partially removed in a central portion thereof on the conductive pad 251 and the connection bump 300 is in contact with the conductive pad 251, electrical conductivity of the semiconductor package of the present inventive concept may be improved. In the connection bumps 300, the first connection bumps may be disposed at the upper surface of the package substrate 110 and the second connection bumps 302 may include a plurality of second connection bumps 302 respectively disposed at the upper surfaces of the plurality of semiconductor chips 200 and disposed at different levels.

The interconnection pattern 350 may be disposed on the package substrate 110 and portions of the upper surfaces of the plurality of semiconductor chips 200. The interconnection pattern 350 may extend in a second direction (e.g., a Y-axis direction) intersecting the first direction (e.g., the X-axis direction) and may contact the connection bumps 300 located at different levels. The interconnection pattern 350 may be in contact with the top of the connection bumps 300, but is not limited thereto and at least a portion of the interconnection pattern 350 may overlap the connection bump 300 in the vertical direction (e.g., the Z-axis direction). The interconnection pattern 350 may be in the form of a bar disposed on the upper surfaces of the plurality of semiconductor chips 200 to correspond to the steps on which the plurality of semiconductor chips 200 are disposed. The interconnection pattern 350 may include a conductive material. According to an embodiment, the interconnection pattern 350 may include the same material as that of the connection bump 300, but is not limited thereto. According to an embodiment, the interconnection pattern 350 may include a barrier layer and a conductive member disposed on the barrier layer, but is not limited thereto. The interconnection pattern 350 may include portions that extend in a vertical direction, perpendicular to the top surface of the substrate 110, and portions that extend horizontally, parallel to the top surface of the substrate 110. The interconnection pattern 350 may additionally include portions covering and contacting a curved surface of connection bumps 300 to which it is connected. For example, the interconnection pattern 350 may be conformally formed on the top surface of the substrate 110, side and top surfaces of the semiconductor chips 200, and outer surfaces of a plurality of connection bumps 300. The interconnection pattern 350 may cover and contact part of the oxide film 252, so that it is not directly connected to the conductive pad 251. By having the interconnection pattern 350 structure electrically connecting the plurality of semiconductor chips 200, space that would normally be occupied by the bonding wires of the related art is not necessary, thereby making the semiconductor package according to the present inventive concept lighter, thinner, and smaller.

The encapsulant 400 may seal at least a portion of each of the plurality of semiconductor chips 200, connection bumps 300, and interconnection patterns 350 on the upper surface of the package substrate 110. The encapsulant 400 may include, for example, a thermosetting resin, such as an epoxy resin, a thermoplastic resin, such as polyimide, or prepreg obtained by impregnating these resins with an inorganic filler, ABF, FR-4, BT, epoxy molding compound (EMC). The encapsulant 400 may be in contact with at least a portion of each of the connection bumps 300 on the package substrate 110, but is not limited thereto.

The external connection conductors 500 may be disposed at the lower surface of the package substrate 110 and may be electrically connected to the wiring circuit 112 and the lower pads 113L. The external connection conductors 500 may physically and/or electrically connect the semiconductor package 100A to an external device. The external connection conductors 500 may include a conductive material and may have a ball, pin, or lead shape. For example, the external connection conductors 500 may be solder balls.

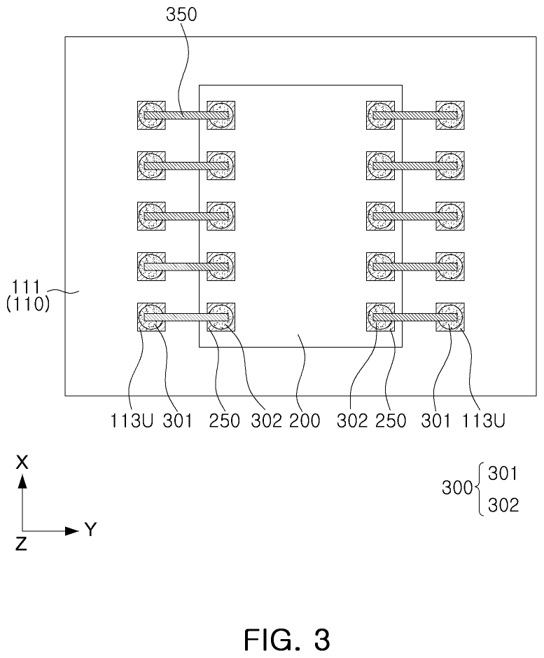

FIG. 3 is a top view schematically illustrating a semiconductor package 100B according to an embodiment of the present inventive concept.

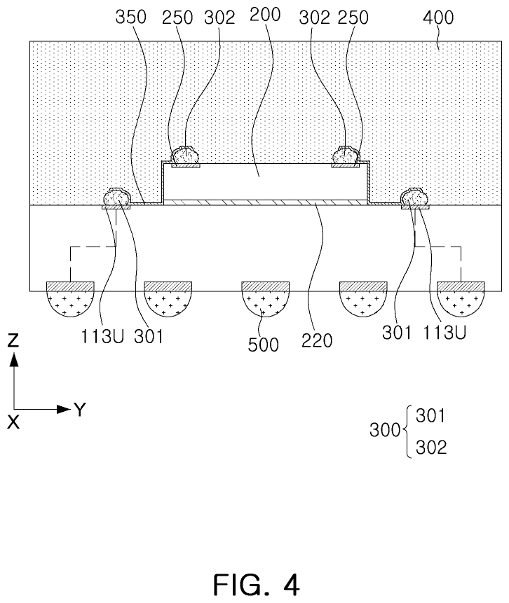

FIG. 4 is a cross-sectional view illustrating the semiconductor package 100B according to an embodiment of the present inventive concept.

Referring to FIGS. 3 and 4, the semiconductor package 100B of an embodiment may have characteristics the same as or similar to the semiconductor package 100A described above with reference to FIGS. 1 to 2B, except that one semiconductor chip 200 is disposed on the package substrate 110 and interconnection patterns 350 are disposed on opposing sides of the semiconductor chip 200. The upper pads 113U may be disposed on the package substrate 110 to be adjacent to the opposing sides of the semiconductor chip 200. The connection bumps 300 may include first connection bumps 301 disposed on the upper pads 113U and second connection bumps 302 disposed on the bonding pad structures 250. The interconnection pattern 350 may extend along the corresponding first connection bump 301 and the second connection bump 302 and may electrically connect the first connection bump 301 to the second connection bump 302.

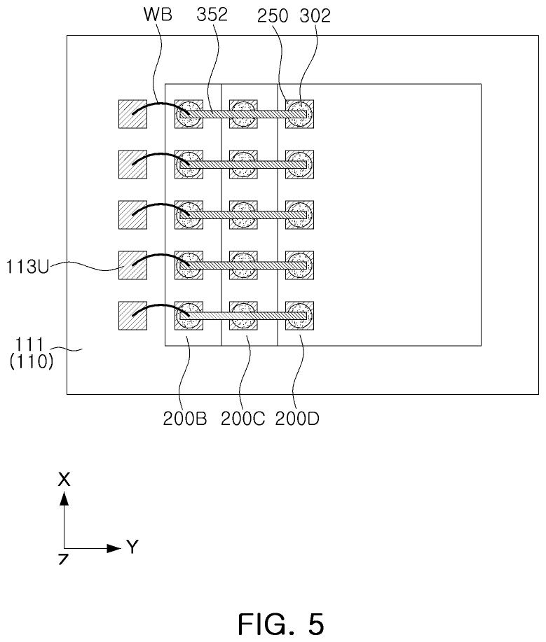

FIG. 5 is a top view schematically illustrating a semiconductor package 100C according to an embodiment of the present inventive concept.

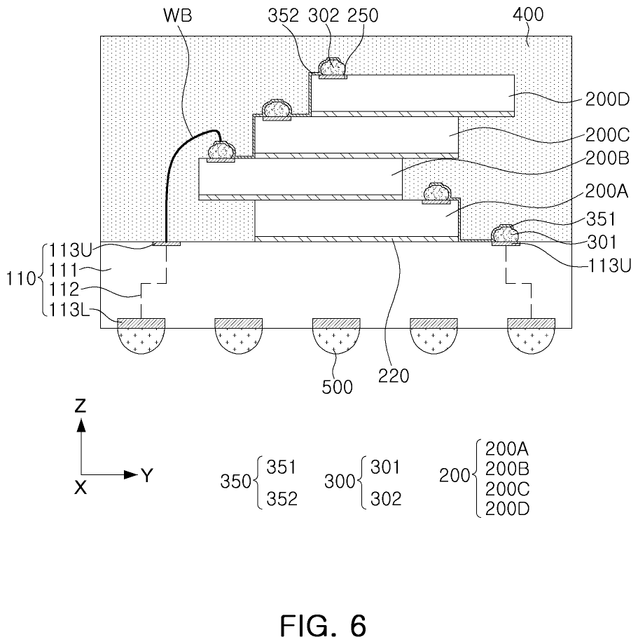

FIG. 6 is a cross-sectional view illustrating a semiconductor package 100C according to an embodiment of the present inventive concept.

Referring to FIGS. 5 and 6, a semiconductor package 100C of an embodiment may have characteristics the same as or similar to those described above with reference to FIGS. 1 to 4, except that the semiconductor package 100C further includes a bonding wire WB electrically connecting the semiconductor chip 200 to the package substrate 110. A plurality of semiconductor chips 200 may be disposed on the upper surface of the package substrate 110. Among the plurality of semiconductor chips 200, some semiconductor chips 200B, 200C, and 200D may be arranged in a staircase shape offset in the second direction (e.g., a+Y-direction), but the lowermost semiconductor chip 200A may be disposed to be offset in a different direction (e.g., a−Y-direction) from the upper semiconductor chips 200B, 200C, and 200D disposed on the lowermost semiconductor chip 200A. The plurality of semiconductor chips 200 may include bonding pad structures 250, respectively. The connection bumps 302 may be formed on the bonding pad structures 250, respectively. The interconnection pattern 350 may include a plurality of interconnection patterns 350 arranged at different levels. The lowermost semiconductor chip 200A may be electrically connected to the upper pads 113U disposed to be adjacent to the bonding pad structure 250 of the lowermost semiconductor chip 200A through a first interconnection pattern 351. The upper semiconductor chips 200B, 200C, and 200D may electrically connect bonding pad structures 250 arranged to be adjacent to each other through the second interconnection pattern 352. Among the upper semiconductor chips 200B, 200C, and 200D, at least one semiconductor chip excluding the uppermost semiconductor chip 200D may be electrically connected to the upper pads 113U of the package substrate 110 through the bonding wire WB. The top of the bonding wire WB may be located on a level lower than the top of at least one interconnection pattern 352 among the plurality of interconnection patterns 350. Specifically, the top of the bonding wire WB may be on a level lower than that of the top of the second interconnection pattern 352.

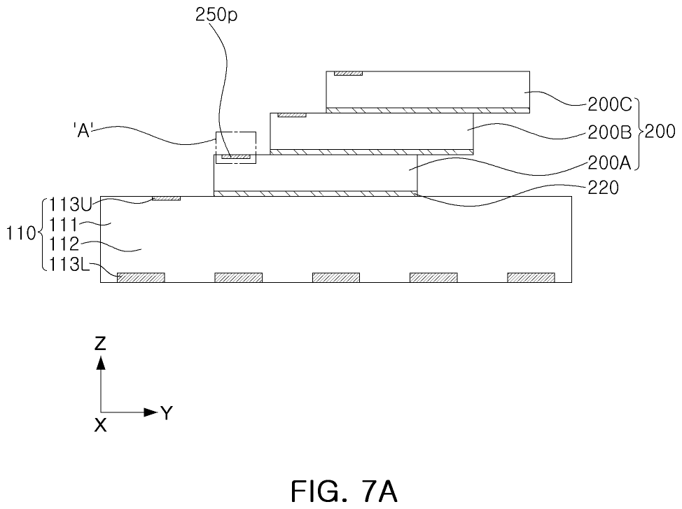

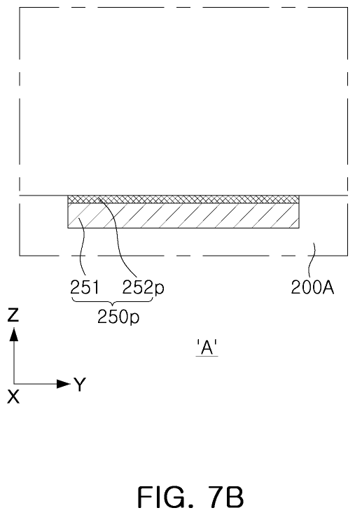

FIGS. 7A to 10 are cross-sectional views and partially enlarged views schematically illustrating a manufacturing process of the semiconductor package 100A according to an embodiment of the present inventive concept.

FIGS. 7A, 8A, 9A, and 10 are cross-sectional views schematically illustrating a manufacturing process for manufacturing the semiconductor package 100A according to an embodiment of the present inventive concept, and FIGS. 7B, 8B, and 9B are partially enlarged views illustrating region ‘A’ in FIGS. 7A, 8A, and 9A.

Referring to FIGS. 7A and 7B, a plurality of semiconductor chips 200 may be disposed on the package substrate 110. The plurality of semiconductor chips 200 may be adhered to each other using an adhesive film 220. The adhesive film 220 may be attached to a lower surface of each of the plurality of semiconductor chips 200. Each semiconductor chip 200 of the plurality of semiconductor chips 200 may include preliminary bonding pad structures 250p disposed at an upper surface of the respective semiconductor chip 200 towards one side of the upper surface. The preliminary bonding pad structures 250p on each semiconductor chip 200 may be arranged to be spaced apart from each other in the first direction (e.g., the X-axis direction). Each of the preliminary bonding pad structures 250p may include a conductive pad 251 and a preliminary oxide film 252p disposed on the conductive pad 251.

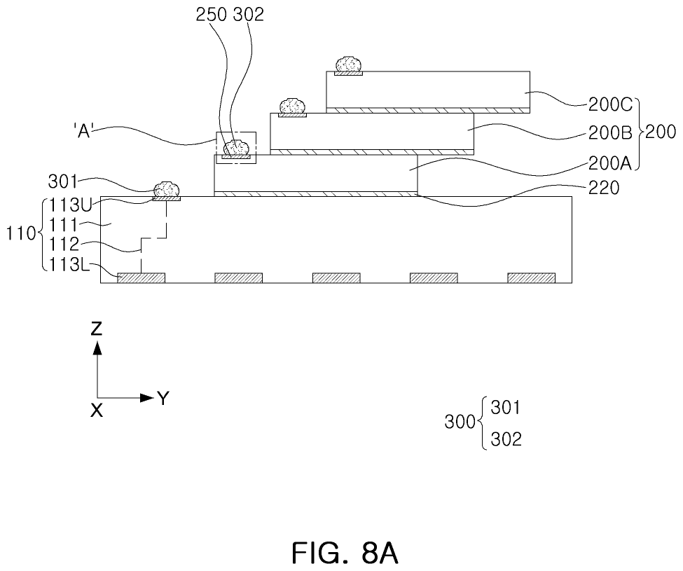

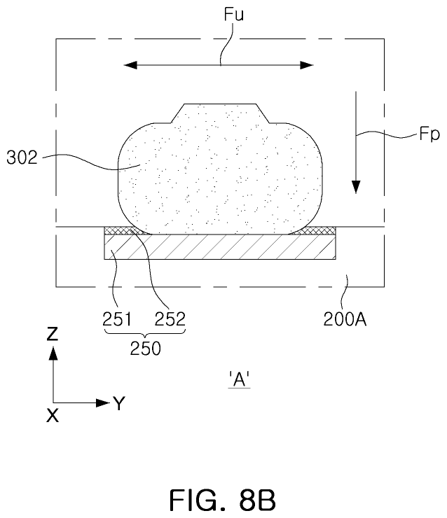

Referring to FIGS. 8A and 8B, bonding pad structures 250 and connection bumps 300 respectively disposed on the bonding pad structures 250 may be formed. The connection bumps 300 may be formed by pressing a metal material into the upper surface of each semiconductor chip 200 in a direction perpendicular to the upper surface of each of the semiconductor chips 200. In the process of pressing the metal material, pressure may be applied in a vertical direction Fp, friction and vibrations may occur in a horizontal direction Fu, and a central portion of the preliminary oxide film 252p (see FIG. 7B) May be removed as a result. The process of pressing the metal material and thereby removing the central portion of the preliminary oxide film 252p may form the oxide film 252. Each of the bonding pad structures 250 may include a conductive pad 251 and an oxide film 252 disposed on the conductive pad 251. The connection bumps 302 may be in contact with the conductive pad 251 without the oxide film 252 disposed therebetween, and at least a portion of each of the connection bumps 302 may be surrounded by the oxide film 252.

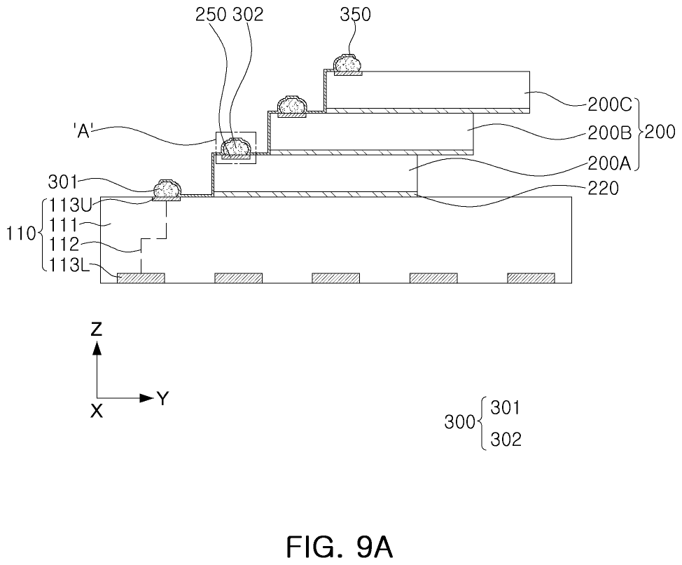

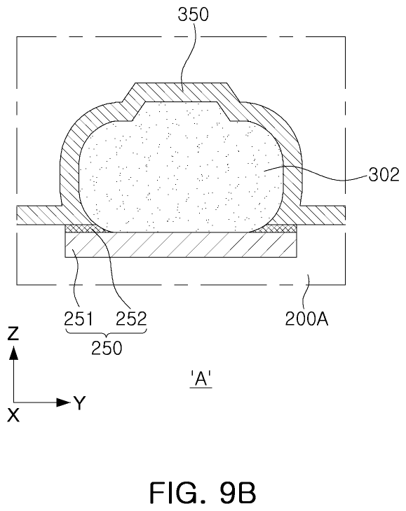

Referring to FIGS. 9A and 9B, the interconnection pattern 350 connecting the connection bumps 302 and extending in the second direction may be formed. The interconnection pattern 350 may be formed through a plating process or a process of dispensing a metal material. In the case of forming the interconnection pattern 350 through a plating process, the interconnection pattern 350 may include a barrier layer and a conductive member disposed on the barrier layer. The barrier layer may correspond to a portion of a seed layer in the plating process. In the case of forming the interconnection pattern 350 by dispensing a metal material, the metal material may be formed from the uppermost semiconductor chip 200C to the package substrate 110 along the steps between the plurality of semiconductor chips 200. Both ends of the interconnection pattern 350 may contact each of the first connection bumps 301 on the upper pads 113U of the package substrate 110 and the second connection bumps 302 on the bonding pad structures 250 of the uppermost semiconductor chip 200C. Opposing ends of the interconnection pattern 350 may be partially cut off so as not to cover an outward facing side surface of each of the first connection bump 301 and the second connection bump 302 on the uppermost semiconductor chip 200C but may remain covering an inward facing side surface of the of each of the first connection bump 301 and the second connection bump 302 on the uppermost semiconductor chip 200C, but are not limited thereto.

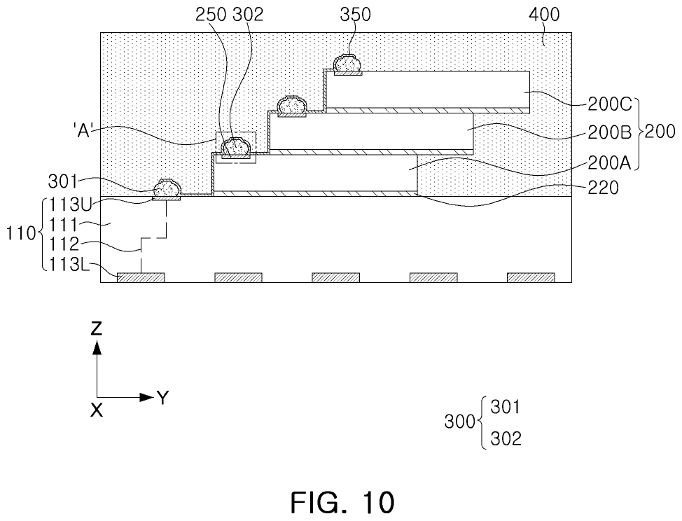

Referring to FIG. 10, an encapsulant 400 sealing at least a portion of each of the package substrate 110 and the plurality of semiconductor chips 200 may be formed. The encapsulant 400 may be formed by applying a sealing material onto the package substrate 110 and curing the sealing material. The encapsulant 400 may cover a portion of each of the connection bumps 300 and the interconnection pattern 350, and the encapsulant 400 may cover a side surface of each of the plurality of semiconductor chips 200 and at least a portion of the adhesive film 220.

Referring to FIGS. 2A and 2B, in a subsequent process, the external connection conductors 500 may be formed on the lower pads 113L on the lower surface of the package substrate 110. The external connection conductors 360 may be attached to the lower pads 113L, and the semiconductor package 100A of the present inventive concept may be formed.

According to embodiments of the present inventive concept, the semiconductor package having improved performance and reliability may be provided by introducing the connection bumps respectively disposed on the conductive pads of the semiconductor chips and the conductive pattern extending in one direction on the upper surface of the semiconductor chips.

While embodiments have been illustrated and described above, it will be apparent to those skilled in the art that modifications and variations could be made without departing from the scope of the present invention as defined by the appended claims.

What is claimed is:

1. A semiconductor package comprising:
a package substrate including an insulating layer, a wiring circuit in the insulating layer, upper pads electrically connected to the wiring circuit, and lower pads electrically connected to the wiring circuit;
a plurality of semiconductor chips stacked in a first direction, perpendicular to an upper surface of the package substrate, each semiconductor chip of the plurality of semiconductor chips located at a particular chip level within the stack of semiconductor chips and including bonding pad structures respectively disposed at one side of an upper surface thereof and spaced apart from each other in a second direction intersecting the first direction;
first connection bumps on the upper pads, each first connection bump electrically connected to a corresponding bonding pad structure and a corresponding upper pad;
second connection bumps on the bonding pad structures, each second connection bump electrically connected to a respective bonding pad structure;
an interconnection pattern extending in a third direction intersecting the first direction and the second direction on the package substrate and the plurality of semiconductor chips and electrically connecting a second connection bump at each chip level of the stack of semiconductor chips to a corresponding second connection bump of the second connection bumps located at a different chip level of the stack of semiconductor chips; and
external connection conductors on a lower surface of the package substrate, each of the external connection conductors electrically connected to a respective lower pad.

2. The semiconductor package of claim 1, wherein the interconnection pattern is conformally formed on the plurality of semiconductor chips.

3. The semiconductor package of claim 1, wherein the interconnection pattern contacts each semiconductor chip of the plurality of chips.

4. The semiconductor package of claim 3, wherein the interconnection pattern, the first connection bumps, and the second connection bumps are formed of a metal material.

5. The semiconductor package of claim 1, wherein the interconnection pattern includes a barrier layer and a conductive member disposed on the barrier layer.

6. The semiconductor package of claim 1, wherein each of the bonding pad structures includes a conductive pad and an oxide film disposed on an upper surface of the conductive pad.

7. The semiconductor package of claim 6, wherein each of the second connection bumps is in contact with a corresponding conductive pad.

8. The semiconductor package of claim 6, wherein the oxide film of each of the bonding pad structures surrounds at least a portion of the corresponding second connection bump.

9. The semiconductor package of claim 6, wherein the interconnection pattern is in contact with the oxide film of the bonding pad structures.

10. The semiconductor package of claim 6, wherein the interconnection pattern is spaced apart from at least one of the conductive pads.

11. The semiconductor package of claim 6, wherein the conductive pad includes aluminum (Al).

12. The semiconductor package of claim 6, wherein, on a plane perpendicular to the first direction, the oxide film has a square shape with a central portion removed.

13. The semiconductor package of claim 1, further comprising adhesive films respectively disposed below each of the semiconductor chips of the plurality of semiconductor chips.

14. The semiconductor package of claim 1, further comprising an encapsulant covering at least a portion of each of the package substrate and the plurality of semiconductor chips.

15. The semiconductor package of claim 14, wherein the encapsulant is in contact with at least a portion of a side surface of each of the second connection bumps.

16. A semiconductor package comprising:
a package substrate including a wiring circuit, with an upper pad and a lower pad each electrically connected to the wiring circuit;
a plurality of semiconductor chips stacked in a first direction, perpendicular to an upper surface of the package substrate, and including bonding pad structures respectively disposed at one side of an upper surface thereof and spaced apart from each other in a second direction;
connection bumps disposed on the bonding pad structures and electrically connected to respective semiconductor chips through the bonding pad structures;
interconnection patterns disposed on the package substrate and the plurality of semiconductor chips, each of the interconnection patterns electrically connecting corresponding connection bumps located at different levels; and
a bonding wire electrically connecting the upper pad to at least one of the connection bumps,
wherein each of the interconnection patterns is arranged at a plurality of different levels, and
a top of the bonding wire is located at a level lower than a top of at least one of the interconnection patterns.

17. The semiconductor package of claim 16, wherein the bonding wire is not in contact with a lowermost semiconductor chip among the plurality of semiconductor chips.

18. The semiconductor package of claim 16, wherein one end of the bonding wire is in contact with at least one of the interconnection patterns.

19. A semiconductor package comprising:
a package substrate including a wiring circuit;
at least one semiconductor chip disposed on an upper surface of the package substrate and including bonding pad structures disposed on one side of an upper surface thereof and spaced apart from each other in a first direction;
connection bumps respectively disposed on the bonding pad structures and having a protruding portion protruding in a first direction perpendicular to the upper surface of the package substrate; and
an interconnection pattern extending in a second direction intersecting the first direction on the package substrate and the at least one semiconductor chip, and electrically connecting corresponding connection bumps located on different levels within the semiconductor package,
wherein the interconnection pattern covers at least a portion of a side surface of the corresponding connection bumps.

20. The semiconductor package of claim 19, wherein the interconnection pattern overlaps at least a portion of each of the corresponding connection bumps in a vertical direction.
